(19) United States
(12) Patent Application Publication
(10) Pub. No.: US 2026/0230082 A1
(43) Pub. Date: Aug. 6, 2026

(54) LOW POWER PHASE DETECTION

(71) Applicant: SEMICONDUCTOR COMPONENTS INDUSTRIES, LLC, Scottsdale, AZ (US)

(72) Inventor: Marek HUSTAVA, Bratislava (SK)

(73) Assignee: SEMICONDUCTOR COMPONENTS INDUSTRIES, LLC, Scottsdale, AZ (US)

(21) Appl. No.: 19/042,666

(22) Filed: Jan. 31, 2025

(51) Int. Cl. H03M 1/06; H03M 1/00

(52) U.S. Cl. CPC H03M 1/0697; H03M 1/002

(57) ABSTRACT

Methods, devices, and systems employing low power digital signal phase detection may employ: an analog to digital converter configured to convert an analog receive signal into a digital receive signal using a sampling clock with a clock frequency equal to at least four times a carrier frequency; a downconverter configured to convert the digital receive signal into a quadrature baseband signal having an in-phase component and a quadrature phase component; and an arctangent module configured to derive a phase signal from the quadrature baseband signal. The foregoing may offer substantial reductions in energy consumption relative to conventional methods for digital signal phase detection.

### CROSS-REFERENCE TO RELATED APPLICATIONS

The present application is filed concurrently with co-owned U.S. application Ser. No. 19/042,615 titled “Robust Flow Sensor, Controller, and Method” by inventor Marek Hustava, which is hereby incorporated herein by reference in its entirety.

### TECHNICAL FIELD

The present disclosure pertains to the field of digital signal processing, particularly as it may be applied for ultrasonic sensing. More specifically, it relates to low power phase detection of a receive signal using an analog to digital converter and applications thereof.

### BACKGROUND

Signal phase detection is employed in diverse applications ranging from astronomy to scanning electron microscopy. In many cases, such as ultrasonic sensing and environmental monitoring, it is desirable to perform phase detection using minimal energy consumption. As a more particular example, the ultrasonic flow meters employed in industrial processes, environmental monitoring, and fluid management systems may employ signal phase detection to enhance measurement precision, reliability, and functional safety. Where low power phase detection can be provided, such benefits can be more efficiently achieved.

### SUMMARY

In light of the foregoing, the present disclosure explores methods, devices, and systems employing low power digital signal phase detection. One illustrative phase detector includes: an analog to digital converter configured to convert an analog receive signal into a digital receive signal using a sampling clock with a clock frequency equal to at least four times a carrier frequency; a downconverter configured to convert the digital receive signal into a quadrature baseband signal having an in-phase component and a quadrature phase component; and an arctangent module configured to derive a phase signal from the quadrature baseband signal.

An illustrative phase detection method includes: converting an analog receive signal into a digital receive signal using a sampling clock with a clock frequency equal to at least four times a carrier frequency; downconverting the digital receive signal into a quadrature baseband signal having an in-phase component and a quadrature phase component; and deriving a phase signal from the in-phase component and the quadrature phase component.

An illustrative sensor controller includes: an analog to digital converter configured to convert an analog receive signal from an ultrasonic transducer into a digital receive signal; a downconverter configured to convert the digital receive signal into a quadrature baseband signal having an in-phase component and a quadrature phase component; and an arctangent module configured to derive a phase signal from the quadrature baseband signal. The analog to digital converter uses a sampling clock with a clock frequency equal to at least four times a nominal carrier frequency of the analog receive signal. The downconverter includes a counter coupled to a lookup table to generate a cosine signal having the nominal carrier frequency and a sine signal having the nominal carrier frequency.

Each of the foregoing illustrative implementations can be embodied individually or conjointly, together with one or more of the following optional features in any suitable combination: 1. the sampling clock is derived from a carrier signal shared with a transmit signal generator. 2. the phase signal indicates a phase of the analog receive signal relative to the carrier signal. 3. the arctangent module includes a look-up table to convert a ratio of the quadrature phase component and in-phase component to a phase angle. 4. the arctangent module includes a circuit configured to calculate a phase angle using a polynomial approximation of an arctangent function. 5. the downconverter includes an in-phase multiplier configured to multiply the digital receive signal with a cosine signal having the carrier frequency, and a quadrature phase multiplier configured to multiply the digital receive signal with a sine signal having the carrier frequency. 6. the downconverter includes a modulo-8 counter coupled to a lookup table to generate the cosine signal and the sine signal. 7. a derivative module configured to derive a frequency offset signal from the phase signal. 8. a suppression module configured to suppress output of the phase signal when a magnitude of the digital receive signal falls below a predetermined threshold. 9. a processor that determines at least one of: a distance, a velocity, and a flow rate, based on the phase signal.

### BRIEF DESCRIPTION OF THE FIGURES

FIG. 1 is a plan view of an illustrative flow meter arrangement for a closed channel flow.

FIG. 2 is a block diagram of an illustrative sensor controller with supporting components for ultrasonic transmission and reception.

FIG. 3 is a block diagram of illustrative phase calculation circuitry that may be used within the sensor controller.

FIG. 4 is a graph showing cosine and sine function values that may be stored in a look-up table for low-power phase calculation.

FIG. 5 is a schematic of an illustrative magnitude testing module.

FIG. 6 is a block diagram of illustrative signal processing and diagnostic circuitry within the sensor controller.

FIG. 7 is a flow diagram of an illustrative low power phase sensing method.

### DETAILED DESCRIPTION

The drawings and following description do not limit the disclosure, but on the contrary, they provide the foundation for one of ordinary skill in the art to understand all modifications, equivalents, and alternatives falling within the scope of the claim language.

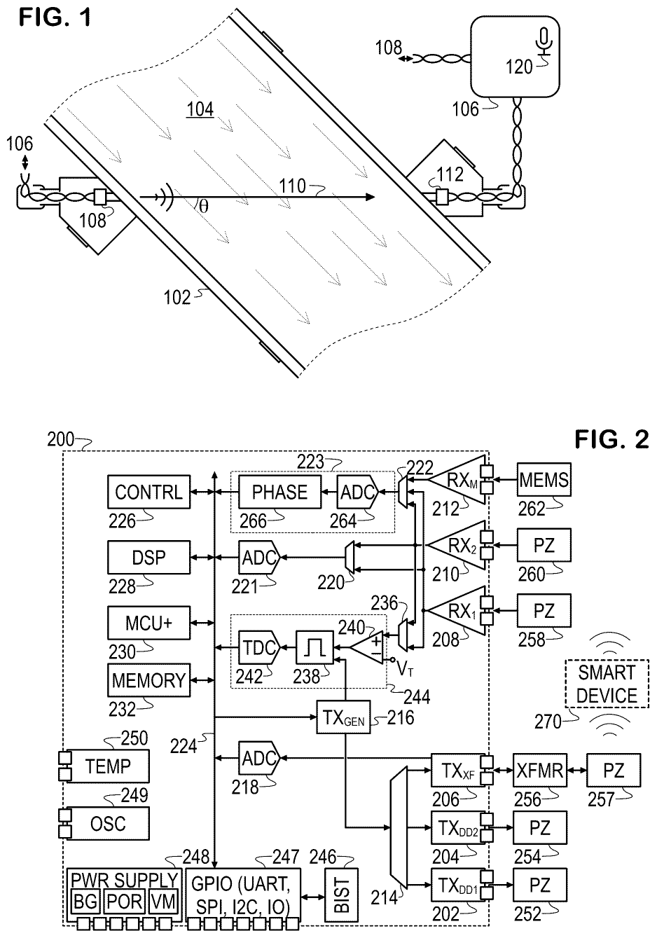

FIG. 1 shows an illustrative context in which the described sensor controller and methods may be employed. FIG. 1 shows a closed-channel fluid measurement system with a pipe 102 through which a fully confined fluid flow 104 is directed. The fluid may be a liquid, a gas, or any flowable composition including inhomogeneous mixtures with suspended solids. The pipe 102 has a predetermined cross-sectional flow area A and may be configured to provide a reasonably uniform laminar flow stream having an average flow velocity v along the pipe's longitudinal axis.

A sensor controller 106 is connected to the system, controlling the operation of ultrasonic transducers 108, 112. An ultrasonic sending transducer 108 is positioned on one side of the pipe 102, emitting an acoustic burst or other acoustic signals along a propagation path 110 across a diameter of the pipe intersecting the longitudinal axis at an angle θ. On the opposite side, an ultrasonic receiving transducer 112 is situated to capture the acoustic signals sent by the sending transducer 108. Sending transducer 108 may further be configured to receive reflections of the acoustic bursts from, e.g., bubbles, droplets, or particles entrained in the fluid flow. The sensor controller 106 processes these signals to evaluate parameters such as time of flight and phase shift as described further below.

The sensor controller 106 periodically swaps the roles of the ultrasonic transducers, such that transducer 112 may become the ultrasonic sending transducer and transducer 108 may become the ultrasonic receiving transducer, enabling the sensor controller 106 to determine parameters for opposing propagation directions along path 110. The downstream time of flight is shortened by an amount determined by the fluid flow velocity and the upstream time of flight is similarly extended. By combining (e.g., by determining a difference between reciprocals of) the upstream and downstream measurements, the sensor controller can, in combination with other geometrical parameters (such as pipe diameter and intersection angle θ) measure the fluid flow velocity v. When combined with pipe cross section, the fluid flow velocity enables the sensor controller to determine and monitor a volumetric flow rate. If the fluid density is known or independently measured, the volumetric flow rate can be readily converted to a mass flow rate. Given the tight and well-understood correlation of fluid flow velocity, volumetric flow rate, and mass flow rate, they are each contemplated herein as being encompassed by the generic term “fluid flow rate”.

Certain enhancements to this arrangement provide enhanced reliability and robustness without unduly increasing implementation costs. These enhancements may include an integrated microphone 120 to potentially enhance sound capture capabilities for additional analysis or communication purposes. The arrangement of these components enables precise measurement and monitoring of parameters associated with fluid flow 104.

FIG. 2 shows an illustrative sensor controller 200, which may be implemented as a monolithic integrated circuit chip having an arrangement of interconnected components, designed to handle ultrasonic signal processing and communication tasks. At the heart of the system, the control logic 226 coordinates signal flow and processing through an internal bus 224. The transmitter components, including transmitter 202, transmitter 204, and transmitter 206, are configured to deliver drive signals to various ultrasonic sending transducers, such as ultrasonic sending transducer 252, ultrasonic sending transducer 254, and (via a transformer 256) ultrasonic sending transducer 257, generating acoustic bursts that emanate from the selected one of the transducers. To offer configuration flexibility, transmitters 202, 204 may be direct-drive transmitters providing drive signals having a specified voltage waveform, while transmitter 206 may be a current driver configured to provide a drive signal having a specified current waveform to a transformer 256, enabling the transformer to supply an elevated voltage signal to transducer 257.

Transmitter 206 may further provide a sensing voltage to analog-to-digital converter (ADC) 218, enabling the sensor controller 200 to monitor the voltage response of the ultrasonic sending transducer 257 during driving and/or post-driving reverberation. Transmitters 202, 204 may be configured for current or impedance monitoring, enabling the sensor controller 200 to monitor the impedance of the ultrasonic sending transducers 252, 254 during driving. Though three sending transducers are shown in FIG. 2, most contemplated sensor arrangements will employ only one or two ultrasonic sending transducers.

Sensor controller 200 further includes a receiver 208, receiver 210, and receiver 212, respectively coupled to an ultrasonic receiving transducer 258, ultrasonic receiving transducer 260, and microphone 262. Transducers 258, 260, 262 are all shown for completeness; in practice one or more of these may be omitted. While ultrasonic receiving transducers 258, 260 are shown and implementable as individual elements, it is contemplated that each receiving transducer may also serve as one of the ultrasonic sending transducers 252, 254, 257. For example, the sensor may have a single transducer that is driven by one of the transmitters to generate an acoustic burst before being used by one of the receivers to detect a reflection of the acoustic burst. As another example, the sensor may have a transducer that is used to generate an acoustic burst and a second transducer used to receive the response. In this case, the second transducer can be used to generate a subsequent acoustic burst and the first transducer may be used to receive a subsequent response. The ultrasonic sending and receiving transducers may be piezoelectric (PZ) elements with optional supporting discrete components. Microphone 262 may similarly be a piezoelectric element, though a micro-electromechanical systems (MEMS) transducer may be preferred for higher sensitivity.

A demultiplexer 214 forwards the digital transmit signal from transmit signal generator 216 to a selected one of the transmitters 202-206 to drive the corresponding ultrasonic sending transducer to generate an acoustic burst. Conversely, multiplexer 220 selectively couples an analog receive signal from receiver 208, 210 to ADC 221, which digitizes the selected receive signal. Multiplexer 222 selectively couples an analog receive signal from one of receivers 208, 210, 212 to a phase detector 223, which includes an ADC 264 to digitize the analog receive signal and phase calculation logic 266, which measures the receive signal phase as discussed further below.

Control logic 226 coordinates the operation of components 202-223 to deliver digital receive signals or signal phase measurements to digital signal processor (DSP) 228, microcontroller 230, memory 232, and/or application specific integrated circuitry (ASIC) modules within control logic 226. In addition to providing software or firmware instructions and programmable parameters for the signal processing components, memory 232 may provide buffering of the digital receive signals, intermediate signal streams, and measurement signals, but also may provide nonvolatile storage for logs of the measurement results that can be stored for later retrieval or delivered in real time to other components or systems.

Signal processing tasks can be allocated in various ways among the microcontroller unit (MCU) 230, DSP 228, and control logic 226, which may be primarily distinguishable in terms of their balance between software and hardware implementation of their desired functionality. FIG. 2 shows the phase shift measurement circuit 223 as being implemented mainly within application specific circuitry, but the disclosed modules can be distributed in other ways, with some functions implemented by the digital signal processor 228 and others by software in the microcontroller.

FIG. 2 further shows a multiplexer 236 directing a selected analog receive signal from receivers 208, 210 to a time-of-flight measurement circuit 244. The time-of-flight measurement circuit 244 includes a pulse generator 238, a comparator 240, and a time-to-digital converter TDC 242. When the transmit signal generator 216 operates to generate an acoustic burst, it provides an asserted Start signal to pulse generator 238. The pulse generator 238 asserts its output signal until the Stop signal from the comparator 240 is asserted. The comparator 240 asserts the Stop signal when the selected analog receive signal exceeds a predetermined threshold voltage V_{T}, indicating the arrival of an acoustic burst in the selected receive signal. In some alternative implementations, the pulse generator 238 incorporates a zero-crossing detector for increased precision. The pulse generator 238 de-asserts its output (1) after the envelope of the receive signal exceeds the threshold voltage, and (2) the zero-crossing detector detects a subsequent zero crossing in the receive signal. TDC 242 converts width of the pulse output by pulse generator into a digital value indicating its duration. Suitable implementation examples may include: (1) a high frequency clock counter, and (2) an integrator coupled to an analog-to-digital converter.

Sensor controller 200 may further include supporting components such as built-in self-test (BIST) circuitry 246, a general-purpose input/output (GPIO) interface module 247, a power supply 248, an oscillator 249, and a temperature sensor circuit 250. The BIST circuitry 246 may be configured to test functionality of the various other components including the transmitters, the receivers, the signal processing circuitry, and the control logic. The GPIO interface 247 may be configured to provide digital input/output signal functionality for commands, control signals, and data. Various digital I/O and serial communications protocols may be supported including, e.g., UART, SPI, I2C, and 5V IO.

Power supply 248 provides power conditioning using one or more bandgap (BG) references, a voltage monitoring (VM) circuit, and a power-on reset (POR) module to implement the sequence of power-on operations. One or more oscillators 249 may employ a crystal to generate various on-chip clock signals for synchronizing operations of the various other components. The temperature sensor circuit 250 may be coupled to an external thermocouple or other temperature sensor to monitor environmental conditions.

An additional feature that may be offered by the sensor controller 200 is near range communication with a smart device 270 such as a smart phone or similar device having a microphone that can sense ultrasonic signals and a speaker that can transmit ultrasonic signals. The sensor controller 200 and smart device 270 can modulate and demodulate ultrasonic signals to transmit and receive commands and responses to convey data between a sensor and a portable device, facilitating configuration of the sensor, monitoring of the sensor's performance, and retrieval of sensor data.

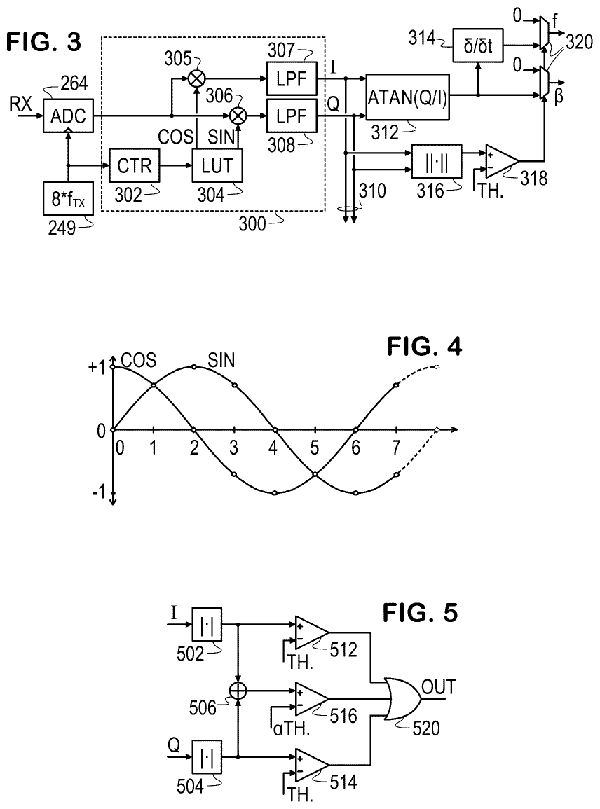

FIG. 3 shows additional detail for an illustrative low-power implementation of phase detection logic 266. In this implementation, the oscillator 249 generates a clock signal at 8x the carrier frequency used for transmitting acoustic bursts. With this sampling clock, the ADC 264 digitizes the analog receive signal. The analog receive signal is expected to be bandlimited by the receivers, such that the higher sampling rate causes the digital receive signal to be oversampled. A frequency downconverter 300 includes a modulo-8 counter/frequency divider 302 using the sampling clock signal to cycle through eight address values for a look up table 30. As shown in FIG. 4, the look up table outputs correspond to cosine and sine functions. The sine function values are shifted by two table locations from the cosine function values. In some contemplated implementations, the look up table is replaced with logic that converts the eight input values to three output magnitudes 0, 0.71, and 1 with suitable sign changes.

The downconverter includes multipliers 435 and 436, which produce products of the digitized receive signal with the cosine and sine function values, respectively, corresponding to the in-phase (I) and quadrature phase (Q) components of the receive signal. Full multiplier implementations may be unnecessary, given that only one non-zero and non-unity coefficient value is employed. Low pass filters 307, 308 remove aliasing and any noise that is out of the signal band associated with the acoustic burst. Though labeled as low pass filters, filters 307, 308 may in practice be bandpass filters centered around the carrier frequency to maximize noise rejection. Filters 307, 308 are implementable as finite impulse response (FIR) filters, but would typically require a higher filter order (and hence more energy consumption) than an infinite impulse response (IIR) filter implementation designed to provide equivalent attenuation of undesired frequencies. Thus IIR filter implementations may be preferred. The downconverter's output is a baseband signal 310 having in-phase and quadrature phase signal components.

An arctangent module 312 converts the baseband signal components into a phase angle measured relative to the carrier signal. The implemented equation is β=arctan(Q/I), where Q and I are the quadrature and in-phase component signal values. Various suitable implementations are known in the literature and include implementation using a look-up table and implementation using a polynomial approximation of the arctan function. Given the extreme nonlinearity of the function around 90 degrees (where the in-phase component values are much smaller than the quadrature phase component values), the lookup table or polynomial approximation may be limited to between −45 and +45 degrees where the magnitude of the in-phase component value is larger than or equal to that of the quadrature phase component. When the magnitude of the in-phase component is smaller, the same table or polynomial approximation can be applied to the arctangent of the inverse ratio: β=90°−arctan(I/Q). This approach limits the look-up table to a reasonable size and enhances precision of the polynomial approximation.

The phase angle measurement produced by the arctangent module 312 may be operated on by a time-differentiation module 314 to determine a frequency offset f between the digital receive signal and the carrier signal. Though not shown here, a low pass filter may be employed to smooth the phase angle and/or frequency offset measurements.

A magnitude module 316 determines a magnitude of the baseband signal for comparison with a predetermined threshold TH by comparator 318. The output of comparator 318 controls multiplexers 320 to suppress output of the phase angle and frequency offset signals when the baseband signal energy is deemed insufficient. Though not shown here, a low-pass filter may be employed to smooth the magnitude measurements and/or otherwise assure that the magnitude is over the threshold for at least a minimum time before the phase measurements are made available.

The magnitude calculation is determined by squaring each of the component signals and summing the squares. While the defining equation for the magnitude calculation then determines a square root of the sum, it is generally easier to square the threshold value supplied to the comparator. Even with this optimization, the squaring operations may be undesirably wasteful in terms of energy consumption. Thus, further optimization of the magnitude calculation may be performed as shown in FIG. 5.

In FIG. 5, absolute value modules 502, 504 determine the absolute value of the baseband signal components. Depending on the binary representations of the signals, this operation may be as trivial as dropping the sign bit. Some signal representations may involve using the sign bit to perform a bitwise exclusive-OR operation of the remaining bits in the binary representation. An adder 506 sums the absolute values. A comparator 512 compares the absolute value of the in-phase component to the threshold TH. A comparator 514 compares the absolute value of the quadrature component to the threshold TH. A third comparator 516 compares the output of adder 506 to a scaled threshold. The scale factor α may be about 1.4, but the exact value may be optimized to the implementation of the other components. A logical OR gate 520 combines the three comparator outputs to provide an output signal that is asserted when the baseband signal is deemed to have sufficient energy. Though only an approximation of the true magnitude calculation, this approximation is expected to be sufficiently accurate and achievable with reduced energy consumption.

In contrast to the foregoing, conventional phase shift measurements may be expected to involve a discrete Fourier Transform (DFT) or multiple correlations between digitized transmit and receive signals. The complexity of these calculations, taken in combination with the number of signal samples involved, make it prohibitive to implement with low complexity hardware. The low power phase detection approach disclosed herein provides a substantial reduction in energy consumption while being implementable with low complexity hardware.

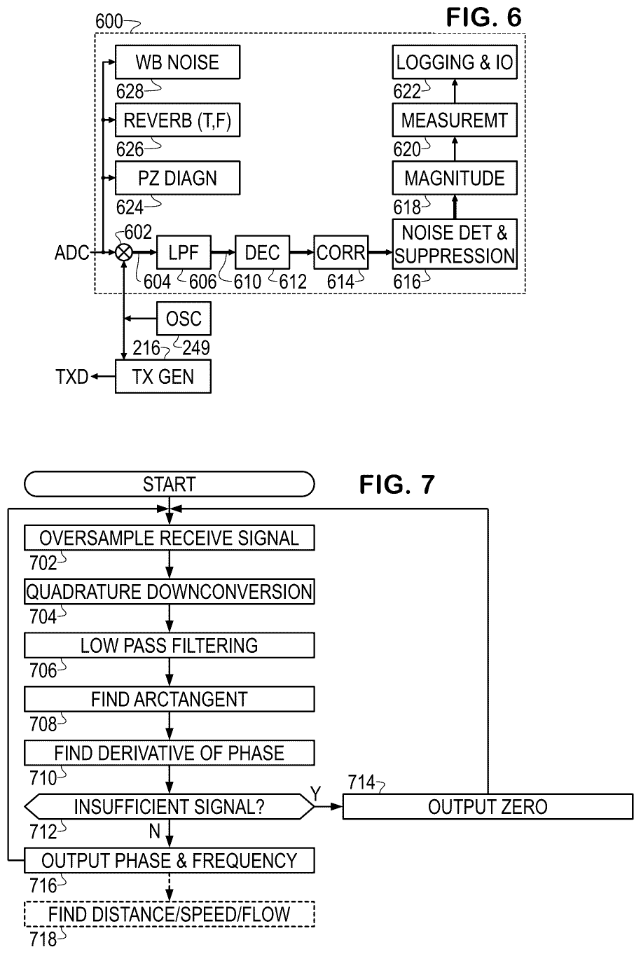

However, sensor controller 200 may nevertheless provide support for more complex signal processing for other functions or for circumstances where energy consumption is less of a concern. The ADC 221 and DSP 228 may cooperate to implement programmable methods for burst detection, distance/time of flight monitoring, and velocity/frequency offset monitoring. FIG. 6 shows a signal processing circuit 600 that employs various components for processing ultrasonic signals. The various components may be implemented as firmware modules implemented by the DSP 228. Oscillator 249 supplies a carrier signal to transmit signal generator 216, which produces the digital transmit signal TXD to generate acoustic bursts for flow rate sensing. (Optionally, transmit signal generator 216 may be further configured to modulate the digital transmit signal to produce modulated ultrasonic signals for near range communications with a smart device.) The carrier signal from oscillator 249 is also supplied to a digital quadrature mixer 602 to downcovert the digital receive signals into a baseband “zero intermediate frequency” ZIF signal 604 having in-phase and quadrature phase components.

A low pass filter 606 processes the ZIF signal 604 to remove noise that is out of the signal band associated with the acoustic burst and to prevent aliasing when the filtered baseband signal 610 is supplied for decimation by the decimator 612. Decimator 612 reduces the sample rate of the filtered baseband signal 610 to reduce processing requirements for subsequent modules. A correlator 614 may use a correlation filter to convert the decimated baseband signal into a correlated signal, indicating when the digitized receive signal includes an acoustic burst that matches an expected waveform. A noise detection and suppression module 616 operates on the correlated signal, applying attenuation compensation to amplify peaks representing echoes and applying a nonlinear function to suppress noise. A magnitude determination module 618 converts the quadrature signal components into a magnitude signal, which may be processed by a time-of-flight measurement module 620 to determine the timing of peaks indicating the travel time of the acoustic burst. Data logging and integration with external systems is facilitated by the logging and I/O module 622, which manages data storage and interfacing.

Additional diagnostic and noise analysis features are provided by the diagnostic module 624, the reverberation module 626, and the wideband noise measurement module 628. The wideband noise measurement module 628 assesses the noise characteristics across the full spectrum of the digitized receive signal. The reverberation module 626 optionally measures the frequency and duration of the transducer's reverberation after transmission of an acoustic burst. The diagnostic module 624, alone or in combination with modules 626, 628, analyzes the digitized response signal to detect and diagnose any transducer fault conditions. Some fault conditions may be indicated by, e.g., an excessively short reverberation periods (which may be due to a disconnected or defective transducer, suppressed vibration, or the like), while others may be indicated by an excessively long reverberation period (defective mounting, inadequate damping resistance, or the like). The diagnostic module 624 may detect and classify multiple such transducer fault conditions, storing the appropriate fault codes in internal registers, from whence they may be communicated to the control logic.

It is noted that modules 612-424 can be reordered or otherwise rearranged as needed to provide the desired signal processing. In at least some implementations, these modules may be disabled at least intermittently to reduce processing requirements and associated power consumption. The DSP 228 may in some configurations omit block s 602-614 in favor of retrieving phase and frequency signal measurements from phase detection logic 266, deriving distance/time of flight measurements and velocity/frequency offset measurements therefrom.

FIG. 7 is a flow diagram of an illustrative phase detection method implementable by phase detector 223. It begins in block 702 with oversampling of the analog receive signal by an ADC. The oversampling is preferably performed with a sampling clock corresponding to the carrier signal for the transmitted signal, but having a frequency at least four times higher, and preferably eight times higher. The 4x frequency may be preferred where a higher clock frequency is difficult to generate without excessive jitter, whereas the 8x frequency may be preferred where better control of signal harmonics is desired.

In block 704, a quadrature mixer downconverts the digital receive signal to provide a baseband signal having in-phase and quadrature phase components. In block 706, filters operate on the component signals to eliminate aliasing and reduce noise content. An arctangent module combines the component signals to provide a phase measurement signal in block 708. A differentiation module calculates a time derivative of the phase measurement signal to provide a frequency offset measurement in block 710. In block 712, a magnitude and comparator circuit determines whether the baseband signal has sufficient signal energy to make the phase measurement meaningful, and if not, in block 714, the circuit zeros out the output to suppress the measurements. Otherwise, in block 716, the measurements are forwarded for use by other components in block 718. Those components may use the phase and frequency offset measurements to derive travel time, distance, velocity, and flow rates. The sensor controller may communicate the monitored parameter measurements to a logging service or monitoring system and/or store them for later retrieval. The method returns to the beginning to repeat.

Numerous modifications, equivalents, and alternatives will become apparent to those skilled in the art once the above disclosure is fully appreciated. Though the foregoing discussion has focused on ultrasonic sensing applications, the disclosed phase detection techniques are applicable to all sensing and communication systems where low power digital phase detection is desired. It is intended that the following claims be interpreted to embrace all such modifications, equivalents, and alternatives where applicable.

What is claimed is:

1. A phase detector comprising:
an analog to digital converter configured to convert an analog receive signal into a digital receive signal using a sampling clock with a clock frequency equal to at least four times a carrier frequency;
a downconverter configured to convert the digital receive signal into a quadrature baseband signal having an in-phase component and a quadrature phase component; and
an arctangent module configured to derive a phase signal from the quadrature baseband signal.

2. The phase detector of claim 1, wherein the sampling clock is derived from a carrier signal, and wherein the phase signal indicates a phase of the analog receive signal relative to the carrier signal.

3. The phase detector of claim 2, wherein the carrier signal is shared with a transmit signal generator.

4. The phase detector of claim 1, wherein the arctangent module includes a look-up table to convert a ratio of the quadrature phase component and in-phase component to a phase angle.

5. The phase detector of claim 1, wherein the arctangent module includes a circuit configured to calculate a phase angle using a polynomial approximation of an arctangent function.

6. The phase detector of claim 1, wherein the downconverter includes an in-phase multiplier configured to multiply the digital receive signal with a cosine signal having the carrier frequency, and a quadrature phase multiplier configured to multiply the digital receive signal with a sine signal having the carrier frequency.

7. The phase detector of claim 6, wherein the clock frequency is eight times a carrier frequency and wherein the downconverter includes a modulo-8 counter coupled to a lookup table to generate the cosine signal and the sine signal.

8. The phase detector of claim 1, further comprising a derivative module configured to derive a frequency offset signal from the phase signal.

9. The phase detector of claim 1, further comprising a suppression module configured to suppress output of the phase signal when a magnitude of the digital receive signal falls below a predetermined threshold.

10. A phase detection method comprising:
converting an analog receive signal into a digital receive signal using a sampling clock with a clock frequency equal to at least four times a carrier frequency;
downconverting the digital receive signal into a quadrature baseband signal having an in-phase component and a quadrature phase component; and
deriving a phase signal from the in-phase component and the quadrature phase component.

11. The phase detection method of claim 10, wherein the sampling clock is derived from a carrier signal, and wherein the sampling clock has clock frequency equal to eight times the carrier frequency.

12. The phase detection method of claim 10, wherein said deriving includes using a look-up table to convert a ratio of the quadrature phase component and in-phase component to a phase angle.

13. The phase detection method of claim 10, wherein said deriving includes using a circuit configured to implement a polynomial approximation of an arctangent function.

14. The phase detection method of claim 10, wherein said downconverting includes multiplying the digital receive signal with a cosine signal having the carrier frequency, and multiplying the digital receive signal with a sine signal having the carrier frequency.

15. The phase detection method of claim 14, wherein said downconverting further includes generating the cosine signal and the sine signal using a counter coupled to a lookup table.

16. The phase detection method of claim 10, further comprising suppressing output of the phase signal when a magnitude of the digital receive signal falls below a predetermined threshold.

17. A sensor controller comprising:
an analog to digital converter configured to convert an analog receive signal from an ultrasonic transducer into a digital receive signal, the analog to digital converter configured to use a sampling clock with a clock frequency equal to eight times a nominal carrier frequency of the analog receive signal;
a downconverter configured to convert the digital receive signal into a quadrature baseband signal having an in-phase component and a quadrature phase component, the downconverter including:
a modulo-8 counter coupled to a lookup table to generate a cosine signal having the nominal carrier frequency and a sine signal having the nominal carrier frequency; and
an arctangent module configured to derive a phase signal from the quadrature baseband signal.

18. The sensor controller of claim 17, wherein the downconverter includes an in-phase multiplier configured to multiply the digital receive signal by the cosine signal, and a quadrature phase multiplier configured to multiply the digital receive signal by the sine signal.

19. The sensor controller of claim 17, further comprising a derivative module that converts the phase signal into a frequency offset signal.

20. The sensor controller of claim 17, further comprising a processor that determines at least one of: a distance, a velocity, and a flow rate, based on the phase signal.
